(19) United States
(12) Patent Application Publication
(10) Pub. No.: US 2023/0361152 A1
(43) Pub. Date: Nov. 9, 2023

(54) COLOR-DISPLAY LIGHT-EMITTING-DIODE OPTOELECTRONIC DEVICE

(71) Applicant: Aledia, Echirolles (FR)

(72) Inventors: Mehdi Daanoune, Renage (FR); Walf Chikhaoui, Voiron (FR)

(73) Assignee: Aledia, Echirolles (FR)

(21) Appl. No.: 18/028,471

(22) PCT Filed: Sep. 28, 2021
(86) PCT No.: PCT/EP2021/076573

§ 371 Date: Mar. 24, 2023

(30) Foreign Application Priority Data
Sep. 29, 2020 (FR) FR2009895

(51) Int. Cl. H01L 27/15

(52) U.S. Cl. CPC H01L 27/156

(57) ABSTRACT

An optoelectronic device including first, second, and third three-dimensional light-emitting diodes having an axial configuration. Each light-emitting diode includes a semiconductor element and an active region resting on the semiconductor element. Each semiconductor element corresponds to a microwire, a nanowire, a nanometer- or micrometer-range conical or frustoconical element. The first, second, and third light-emitting diodes are configured to respectively emit first, second, and third radiations at first, second, and third wavelengths. The semiconductor elements of the first, second, and third light-emitting diodes respectively have first, second, and third diameters. The first diameter is smaller than the second diameter and the second diameter is smaller than the third diameter, the first wavelength being greater than the third wavelength and the second wavelength being greater than the first wavelength.

The present patent application claims the priority benefit of French patent application FR20/09895 which is herein incorporated by reference.

### TECHNICAL BACKGROUND

The present invention generally concerns optoelectronic devices comprising three-dimensional semiconductor elements of nanowire or microwire type, and a method of manufacturing the same, and more particularly optoelectronic devices capable of displaying images, particularly a display screen or an image projection device.

### PRIOR ART

A pixel of an image corresponds to the unit element of the image displayed or captured by the optoelectronic device. For the display of color images, the optoelectronic device generally comprises, for the display of each pixel of the image, at least three components, also called display sub-pixels, which each emit a light radiation substantially in a single color (for example, red, green, and blue). The superposition of the radiations emitted by the three display sub-pixels provides the observer with the colored sensation corresponding to the pixel of the displayed image. In this case, the assembly formed by the three display sub-pixels used for the display of a pixel of an image is called display pixel of the optoelectronic device.

There exist optoelectronic devices comprising three-dimensional semiconductor elements of nanowire or microwire type based on III-V compounds enabling to form so-called three-dimensional light-emitting diodes. A light-emitting diode comprises an active region which is the region of the light-emitting diode having most of the electromagnetic radiation supplied by the light-emitting diode emitted therefrom. A three-dimensional light-emitting diode may be formed in a so-called radial configuration, also called core/shell configuration, where the active region is formed at the periphery of the three-dimensional semiconductor element. It may also be formed in a so-called axial configuration, where the active region does not cover the periphery of the three-dimensional semiconductor element but essentially extends along a longitudinal epitaxial growth axis.

Three-dimensional light-emitting diodes in an axial configuration have an emission surface area smaller than that of light-emitting diodes in a radial configuration, but have the advantage of being made of a semiconductor material of better crystalline quality, thus providing a higher internal quantum efficiency, particularly due to a better relaxation of the stress at the interfaces between semiconductor layers.

It is known to cover a light-emitting diode with a photoluminescent material capable of converting the electromagnetic radiation emitted by the active area into an electromagnetic radiation at a different wavelength, particularly higher. However, such photoluminescent materials may have a high cost, have a low conversion efficiency, and have a performance which degrades over time.

It would thus be desirable to be able to form an optoelectronic device comprising light-emitting diodes configured to directly emit radiations in three different colors to obtain a color display without using photoluminescent materials.

Further, the industrial development of the method of manufacturing an active region of an axial-type three-dimensional light-emitting diode based on III-V compounds is a touchy operation. It is known to simultaneously form light-emitting diodes however emitting radiations in different colors by using semiconductor elements of different diameters, the wavelengths of the radiations emitted by the active areas particularly depending on the diameters of the semiconductor elements and on the distance between the semiconductor elements, the wavelength theoretically decreasing with the diameter of the semiconductor element. However, it may be difficult to form light-emitting diodes emitting in blue, which would correspond to semiconductor elements having too small a diameter to be compatible with manufacturing methods at an industrial scale.

### SUMMARY

Thus, an object of an embodiment aims at least partly overcoming the disadvantages of the previously-described optoelectronic devices comprising light-emitting diodes.

Another object of an embodiment is for the active area of each light-emitting diode to comprise a stack of layers of semiconductor materials based on III-V compounds.

Another object of an embodiment is for the optoelectronic device to comprise light-emitting diodes configured to emit light radiations in three different colors without using photoluminescent materials.

Another object of an embodiment is for the optoelectronic device to comprise light-emitting diodes configured to emit light radiations in three different colors and which are manufactured simultaneously.

An embodiment provides an optoelectronic device comprising first, second, and third three-dimensional light-emitting diodes with an axial configuration, each light-emitting diode comprising a semiconductor element and an active region resting on the semiconductor element, each semiconductor element corresponding to a microwire, a nanowire, a nanometer- or micrometer-range conical element, or a nanometer- or micrometer-range frustoconical element, the first light-emitting diodes being configured to emit a first radiation at a first wavelength, the semiconductor elements of the first light-emitting diodes having a first diameter, the second light-emitting diodes being configured to emit a second radiation at a second wavelength, the semiconductor elements of the second light-emitting diodes having a second diameter, and the third light-emitting diodes being configured to emit a third radiation at a third wavelength, the semiconductor elements of the third light-emitting diodes having a third diameter, the first diameter being smaller than the second diameter and the second diameter being smaller than the third diameter, the first wavelength being greater than the third wavelength and the second wavelength being greater than the first wavelength.

According to an embodiment, the first diameter varies from 80 nm to 150 nm.

According to an embodiment, the second diameter varies from 200 nm to 350 nm.

According to an embodiment, the third diameter varies from 370 nm to 500 nm.

According to an embodiment, the first wavelength is in the range from 510 nm to 570 nm.

According to an embodiment, the second wavelength is in the range from 600 nm to 720 nm.

According to an embodiment, the third wavelength is in the range from 430 nm to 490 nm.

According to an embodiment, the device comprises a first optoelectronic circuit bonded to a second electronic circuit, the second electronic circuit comprising electrically-conductive pads, the first optoelectronic circuit comprising pixels and comprising, for each pixel:
a first electrically-conductive layer;
for each of the first, second, and third light-emitting diodes, said semiconductor element extending perpendicularly to the first electrically-conductive layer and in contact with the first electrically-conductive layer and the active region resting on the end of the semiconductor element opposite to the first electrically-conductive layer; and
second, third, fourth, and fifth electrically-conductive layers electrically coupled to the electrically-conductive pads, the second electrically-conductive layer being coupled to the active regions of the first light-emitting diodes, the third electrically-conductive layer being coupled to the active regions of the second light-emitting diodes, the fourth electrically-conductive layer being coupled to the active regions of the third light-emitting diodes, and the fifth electrically-conductive layer being coupled TO the first electrically-conductive layer.

According to an embodiment, each active region comprises a single quantum well or multiple quantum wells.

According to an embodiment, the semiconductor elements and the active regions are made of III-V compounds.

According to an embodiment, the semiconductor elements of the first, second, and third light-emitting diodes are formed by MOCVD.

According to an embodiment, the active regions of the first, second, and third light-emitting diodes are formed by MBE.

According to an embodiment, the semiconductor elements of the first, second, and third light-emitting diodes rest on a substrate and are in contact with a material adapted to the epitaxial growth of the semiconductor elements of the first, second, and third light-emitting diodes.

According to an embodiment, the first, second, and third light-emitting diodes form a monolithic structure.

An embodiment also provides a method of manufacturing the optoelectronic device such as previously defined, comprising the successive steps of:
simultaneously forming the semiconductor elements of the first, second, and third light-emitting diodes; and
simultaneously forming the active regions of the first, second, and third light-emitting diodes on the semiconductor elements of the first, second, and third light-emitting diodes.

According to an embodiment, the method comprises the successive steps of:
simultaneously forming on a support the semiconductor elements of the first, second, and third light-emitting diodes and forming the active regions of the first, second, and third light-emitting diodes on the semiconductor elements of the first, second, and third light-emitting diodes;
forming an electrically-insulating layer between the three-dimensional semiconductor elements of the first, second, and third light-emitting diodes; and
removing the support.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an optoelectronic device comprising microwires or nanowires;

FIG. 2 is a detail view of a portion of FIG. 1;

FIG. 3 is a curve of the variation, obtained by tests, of the central wavelength of radiations emitted by an axial light-emitting diode according to the diameter of the light-emitting diode;

FIG. 4 shows a chromaticity diagram illustrating the color domain capable of being obtained with the optoelectronic device of FIG. 1;

FIG. 5 shows curves, obtained by tests, of the variation of the light intensity according to the wavelength of the radiation emitted by three light-emitting diodes of the optoelectronic device of FIG. 1;

FIG. 6 is a partial simplified cross-section view illustrating the operation of the optoelectronic device of FIG. 1;

FIG. 7A illustrates a step of an embodiment of a method of manufacturing the optoelectronic device shown in FIG. 1;

FIG. 7B illustrates another step of the method;

FIG. 7C illustrates another step of the method;

FIG. 7D illustrates another step of the method;

FIG. 7E illustrates another step of the method;

FIG. 7F illustrates another step of the method;

FIG. 7G illustrates another step of the method;

FIG. 7H illustrates another step of the method;

FIG. 71 illustrates another step of the method;

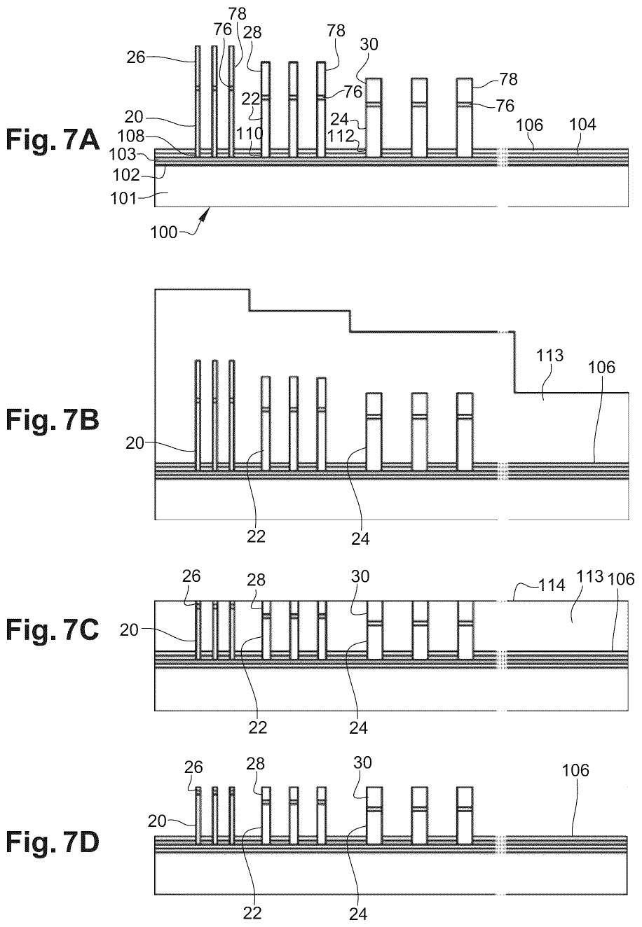

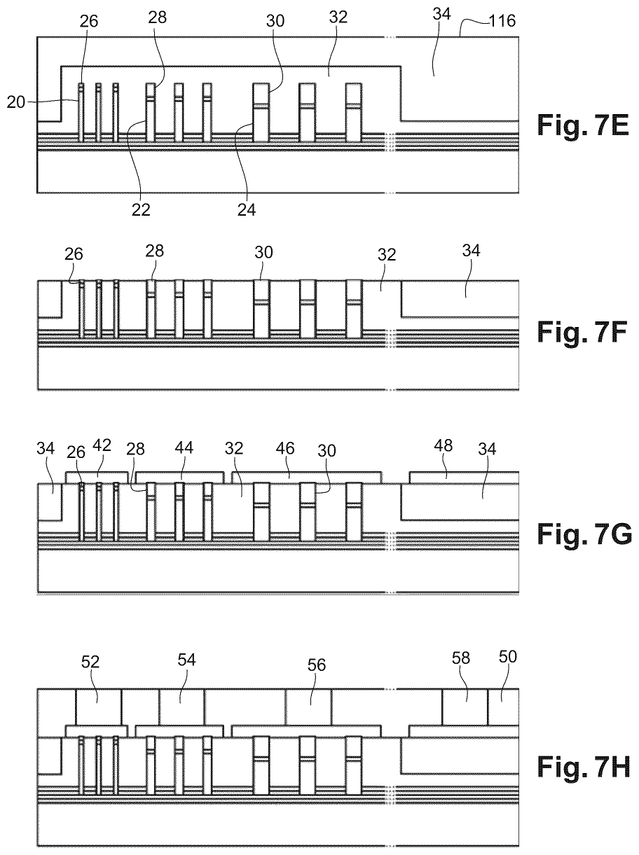

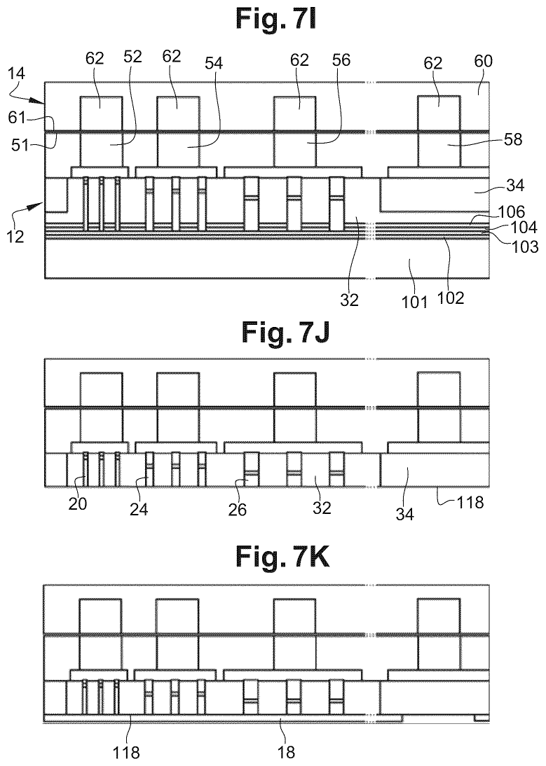

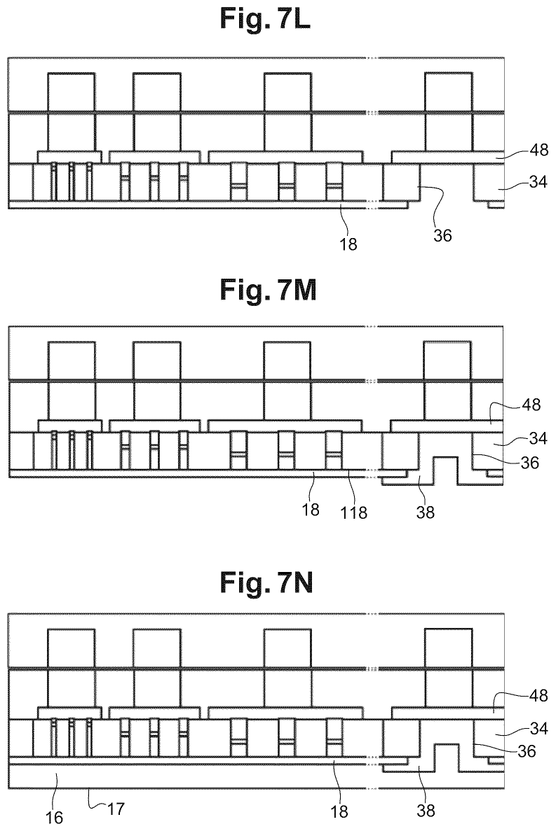

FIG. 7J illustrates another step of the method;

FIG. 7K illustrates another step of the method;

FIG. 7L illustrates another step of the method;

FIG. 7M illustrates another step of the method; and

FIG. 7N illustrates another step of the method.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. En particulier, les moyens pour commander les diodes électroluminescentes d'un dispositif optoélectronique sont bien connus et ne seront pas décrits.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless specified otherwise, the expressions “around”, “approximately”, “substantially” and “in the order of” signify within 10%, and preferably within 5%. Further, unless specified otherwise, the expression “insulating” means “electrically insulating” and the expression “conductive” means “electrically conductive”. In the following description, the inner transmittance of a layer corresponds to the ratio of the intensity of the radiation coming out of the layer to the intensity of the radiation entering into the layer. The absorption of the layer is equal to the difference between 1 and the inner transmittance. In the following description, a layer is said to be transparent to a radiation when the absorption of the radiation through the layer is smaller than 60%. In the following description, a layer is said to be absorbing for a radiation when the absorption of the radiation in the layer is higher than 60%. When a radiation exhibits a generally “bell”-shaped spectrum, for example, of Gaussian shape, having a maximum, wavelength of the radiation, or central or main wavelength of the radiation, designates the wavelength at which the maximum of the spectrum is reached. In the following description, the refraction index of a material corresponds to the refraction index of the material for the wavelength range of the radiation emitted by the optoelectronic device. Unless specified otherwise, the refraction index is considered as substantially constant over the wavelength range of the useful radiation, for example, equal to the average of the refraction index over the wavelength range of the radiation emitted by the optoelectronic device.

The present application particularly concerns optoelectronic devices comprising light-emitting diodes comprising three-dimensional elements, for example, microwires, nanowires, nanometer- or micrometer-range conical elements, or nanometer- or micrometer-range frustoconical elements. In particular, a conical or frustoconical element may be a circular conical or frustoconical element or a pyramidal conical or frustoconical element. In the following description, embodiments are in particular described for electronic devices comprising microwires or nanowires. However, such embodiments may be implemented for three-dimensional elements other than microwires or nanowires, for example, conical or frustoconical three-dimensional elements.

The terms “microwire”, “nanowire”, “conical element”, or “frustoconical element” designate a three-dimensional structure having a shape elongated along a preferred direction, having at least two dimensions, called minor dimensions, in the range from 5 nm to 2.5 μm, preferably from 50 nm to 1 μm, more preferably from 30 nm to 300 nm, the third dimension, called major dimension, being greater than or equal to 1 time, preferably greater than or equal to 5 times, the largest minor dimension, for example, in the range from 1 μm to 5 μm.

In the following description, the term “wire” is used to designate a “microwire” or a “nanowire”. Preferably, the median line of the wire which runs through the centers of gravity of the cross-sections, in planes perpendicular to the preferred direction of the wire, is substantially rectilinear and is called “axis” of the wire hereafter. The wire diameter is here defined as being a quantity associated with the perimeter of the wire at the level of a cross-section. This may be the diameter of a disk having the same surface as the cross-section of the wire. The local diameter, also called diameter hereafter, is the wire diameter at the level of a given height thereof along the wire axis. The mean diameter is the mean, for example, arithmetic, of the local diameters along the wire or a portion thereof.

According to an embodiment, each axial-type light-emitting diode comprises a wire, as previously described, and an active region on the upper portion of the wire. The active region is the region from which most of the radiation supplied by the light-emitting diode is emitted. The active region may comprise confinement means. The active region may comprise a quantum well, two quantum wells, or a plurality of quantum wells, each quantum well being interposed between two barrier layers, the quantum well having a bandgap energy smaller than that of the barrier layers. The active region may comprise a quantum well or quantum wells made of a ternary compound which comprises the group-III and -V elements of the wire and an additional group-III element. The length of the radiation emitted by the active region depends on the incorporated proportion of additional group-III element. For example, the wires may be made of GaN and the quantum well(s) may be made of InGaN. The length of the radiation emitted by the active region accordingly depends on the incorporated proportion of In.

It is known that the proportion of the additional group-III element varies according to the wire diameter. However, documents mentioning such a variation up to now describe an increase in the proportion of the additional group-III element according to the wire diameter, and thus an increase in the wavelength of the radiation emitted by an axial-type light-emitting diode comprising such a wire.

The inventors have shown that there can be observed first, second, and third successive ranges of diameters with an increase in the wavelength of the radiation emitted by a light-emitting diode when the wire diameter increases over the first range of diameters, a decrease in the wavelength of the radiation emitted by a light-emitting diode when the wire diameter increases over the second range of diameters, and a stagnation of the wavelength of the radiation emitted by a light-emitting diode when the wire diameter increases over the third range of diameters.

These results have been advantageously obtained with wires formed by metal-organic chemical vapor deposition (MOCVD) and active regions typically formed by molecular beam epitaxy (MBE).

The previously-described method may be implemented to manufacture an optoelectronic device capable of displaying images, in particular a display screen or an image projection device. In particular, the previously-described method may be implemented to manufacture wires of different mean diameters, for example, first wires having a small mean diameter, second wires having an intermediate diameter, and third wires having a large mean diameter. The active regions formed on the first, second, and third wires will emit radiations at different wavelengths. In particular, the first wires having a small mean diameter will emit a radiation at a first central wavelength, the second wires having an intermediate mean diameter will emit a radiation at a second central wavelength, and the third wires having an intermediate mean diameter will emit a radiation at a third central wavelength, the second wavelength being greater than the first wavelength and the third wavelength being smaller than the first wavelength. A color display screen can then be manufactured.

The forming of the wires by MOCVD advantageously enables to obtain wires having less defects, in particular without defects, as compared with those capable of being obtained by MBE. The forming of the wires by MOCVD advantageously enables to obtain a fast growth of the wires. It further enables to easily obtain wires having diameters complying with the diameter-to-wavelength variation curve implemented according to the present invention. MBE methods advantageously enable to incorporate a greater proportion of the additional group-III element into the quantum wells as compared with the MOCVD method.

Further, the fact for the active region to be only formed on the upper portion of the wire, and not on the lateral sides of the wire advantageously enables to form the active region only on a c plane or semi-polar planes and not on m planes. This advantageously enables to incorporate a greater proportion of the additional group-III element into the quantum wells as compared with the case where the active region is grown on m planes.

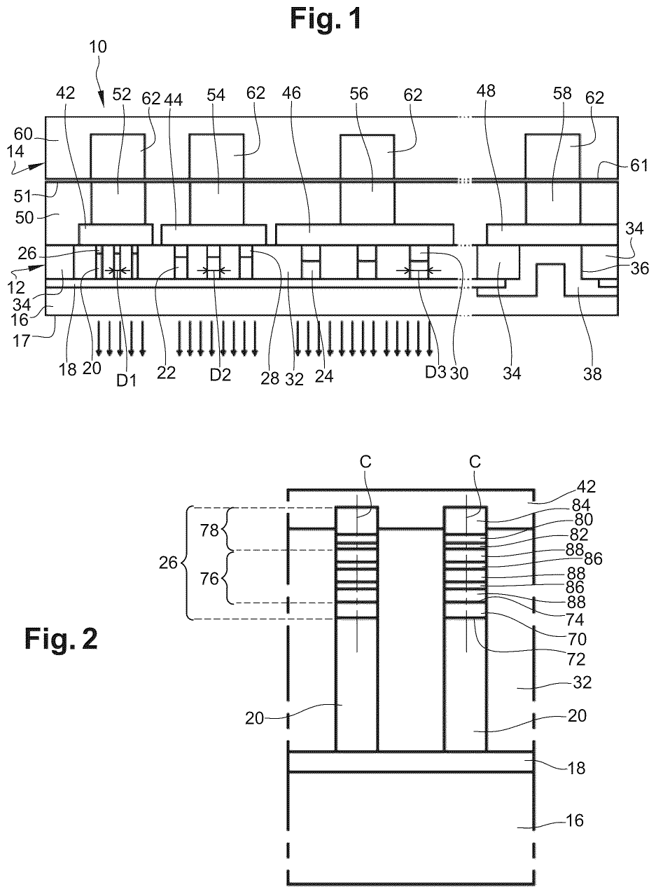

FIG. 1 is a partial simplified cross-section view of an optoelectronic device 10 formed from wires such as previously described and capable of emitting an electromagnetic radiation. According to an embodiment, an optoelectronic device 10 comprising at least two integrated circuits 12 and 14, also called chips, is provided. The first integrated circuit 12 comprises light-emitting diodes. The second integrated circuit 14 comprises electronic components, particularly transistors, used for the control of the light-emitting diodes of the first integrated circuit 12. The first integrated circuit 12 is bonded to the second integrated circuit, for example, by molecular bonding or by a “flip-chip”-type bonding, particularly a ball or microtube “flip-chip” method. First integrated circuit 12 is called optoelectronic circuit or optoelectronic chip in the following description and second integrated circuit 14 is called control circuit or control chip in the following description.

Preferably, optoelectronic chip 12 only comprises light-emitting diodes and elements of connection of these light-emitting diodes and control chip 14 comprises all the electronic components necessary to control the light-emitting diodes of the optoelectronic chip. As a variant, optoelectronic chip 12 may also comprise other electronic components in addition to the light-emitting diodes.

FIG. 1 shows, in its left-hand portion, the elements of optoelectronic chip 12 for a display pixel, the structure being repeated for each display pixel, and, in its right-hand portion, elements adjacent to the display pixels and that may be common to a plurality of display pixels.

Optoelectronic chip 12 comprises, from bottom to top in FIG. 1:
an electrically-insulating layer 16, at least partially transparent to the electromagnetic radiations emitted by the light-emitting diodes and which delimits a surface 17;
an electrically-conductive layer 18, at least partially transparent to the electromagnetic radiations emitted by the light-emitting diodes;
first wires 20 (three first wires being shown) of diameter D1, second wires 22 (three second wires being shown) of diameter D2, and third wires 24 (three third wires being shown) of diameter D3, the first, second, and third wires having axes parallel to one another and perpendicular to surface 17, extending from conductive layer 18 and in contact with conductive layer 18, diameter D1 being smaller than diameter D2 and diameter D2 being smaller than diameter D3;
a first head 26 at the end of each first wire 20 opposite to conductive layer 18, a second head 28 at an end of each second wire 22 opposite to conductive layer 18, and a third head 30 at an end of each third wire 24 opposite to conductive layer 18;
an electrically-insulating layer 32 made of a first electrically-insulating material between wires 20, 22, 24 having a thickness substantially equal to the sum of the height H, measured along the axis of the wires, of wire 20, 22, 24 and of the associated head 26, 28, 30;
an electrically-insulating layer 34 of a second electrically-insulating material, which may be different from the first insulating material or identical to the first insulating material, extending around first insulating layer 32 and of same thickness as insulating layer 32;
an opening 36 extending through insulating layer 34 across the entire thickness of insulating layer 34;
an electrically-conductive layer 38 extending in opening 36 and being in contact with conductive layer 18;
distinct electrically-conductive layers 42, 44, 46, 48, conductive layer 42 being in contact with first heads 26, conductive layer 44 being in contact with second heads 28, conductive layer 46 being in contact with third heads 30, and conductive layer 48 being in contact with conductive layer 38;
an electrically-insulating layer 50 covering conductive layers 42, 44, 46, and 48 and extending between conductive layers 42, 44, 46, and 48 and delimiting a surface 51, preferably substantially planar; and
electrically-conductive pads 52, 54, 56, 58 capable of having a multilayer structure, extending through insulating layer 50 and flush with surface 51, conductive pad 52 being in contact with conductive layer 42, conductive pad 54 being in contact with conductive layer 44, conductive pad 56 being in contact with conductive layer 46, and conductive pad 58 being in contact with conductive layer 48.

Control chip 14 particularly comprises on the side of optoelectronic chip 12 an electrically-insulating layer 60 delimiting a surface 61, preferably substantially planar, and conductive pads 62 flush with surface 61, conductive pads 62 being electrically coupled to conductive pads 52, 54, 56, 58. In the case where control chip 14 is bonded to optoelectronic chip 12 by molecular bonding, conductive pads 62 may be in contact with conductive pads 52, 54, 56, 58. In the case where control chip 14 is bonded to optoelectronic chip 12 by a “flip-chip”-type bond, solder balls or microtubes may be interposed between conductive pads 62 and conductive pads 52, 54, 56, 58.

The assembly formed by each wire 20, 22, 24 and the associated head 26, 28, 30 forms a wire-shaped elementary light-emitting diode in axial configuration.

FIG. 2 is a partial simplified cross-section view of a more detailed embodiment of the head 26 of a light-emitting diode. Heads 28 and 30 may have a similar structure.

Head 26 comprises, from bottom to top in FIG. 2:
possibly a semiconductor layer 70, also called semiconductor cap, made of the same material as wire 20 and doped with a first conductivity type, for example, type N, covering the upper end 72 of wire 20 and having an upper surface 74;
an active region 76 covering the surface 74 of semiconductor layer 70; and
a semiconductor stack 78 covering active region 76 and comprising at least one semiconductor layer 80, having a conductivity type opposite to that of wire 20, covering active region 76.

Each wire 20, 22, 24 and each semiconductor layer 70, 80 are at least partly formed from at least one semiconductor material. According to an embodiment, the semiconductor material is selected from the group comprising III-V compounds, for example, a III-N compound. Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus or arsenic. Generally, the elements in the III-V compound may be combined with different molar fractions. The semiconductor material of wires 20, 22, 24, and/or of semiconductor layers 70, 80 may comprise a dopant, for example, silicon, ensuring an N-type doping of a III-N compound, or magnesium ensuring a P-type doping of a III-N compound.

Stack 78 may further comprise an electron-blocking layer 82 between active region 76 and semiconductor layer 80, and a bonding layer 84 covering semiconductor layer 80 on the side opposite to active region 76, bonding layer 84 being covered with conductive layer 42. Bonding layer 84 may be made of the same semiconductor material as semiconductor layer 80, with the same conductivity type as semiconductor layer 80 but with a greater dopant concentration. Bonding layer 84 enables to form an ohmic contact between semiconductor layer 80 and conductive pad 42.

Active region 76 is the region from which most of the radiation supplied by the light-emitting diode is emitted. According to an example, active region 76 may comprise confinement means. Active region 76 may comprise at least one quantum well, comprising a layer of an additional semiconductor material having a bandgap energy smaller than that of semiconductor layer 70 and of semiconductor layer 80, preferably interposed between two barrier layers, thus improving the confinement of charge carriers. The additional semiconductor material may comprise the III-V compound of doped semiconductor layer 70, 80 having at least one additional element incorporated therein. As an example, in the case of wires 20, 22, 24 made of GaN, the additional material forming the quantum well is preferably InGaN. Active region 76 may be made of a single quantum well or of a plurality of quantum wells.

According to a preferred embodiment, each wire 20, 22, 24 is made of GaN. Semiconductor layer 70 may be made of GaN and be doped with the first conductivity type, for example, type N, in particular with silicon. The height of conductive layer 70, measured along axis C, may be in the range from 10 nm to 1 μm, for example, in the range from 20 nm to 200 nm. Active region 76 may comprise a single or a plurality of quantum wells, for example, made of InGaN. Active region 76 may comprise a single quantum well which extends between semiconductor layers 70, 80. As a variant, it may comprise multiple quantum wells and it is then formed of an alternation along axis C of quantum wells 86, for example, made of InGaN, and of barrier layers 88, for example, made of GaN, three GaN layers 88 and two InGaN layers 86 being shown as an example in FIG. 2. GaN layers 88 may for example be N- or P-type doped, or non-doped. The thickness of active region 76, measured along axis C, may be in the range from 2 nm to 100 nm. Conductive layer 80 may be made of GaN and be doped with the second conductivity type opposite to the first type, for example, type P, in particular with magnesium. The thickness of semiconductor layer 80 may be in the range from 20 nm to 100 nm. When an electronic-blocking layer 82 is present, it may be made of GaN or of a ternary III-N compound, for example, AlGaN or AlInN, advantageously P-type doped. This enables to increase the radiative combination rate in active region 76. The thickness of electron-blocking layer 82 may be in the range from 10 nm to 50 nm. Electron-blocking layer 82 may correspond to a superlattice of InAlGaN or of AlGaN and GaN layers, each layer for example having a 2-nm thickness.

Tests have been carried out. For the tests, wires 20 were made of GaN. Active regions 76 were each comprised of seven quantum wells made of InGaN separated by GaN layers. Wires 20 have been formed by MCVD and active regions 76 have been formed by MBE. The wavelength of the radiation emitted by active regions 76 has been measured, as well as the diameter of wires 20.

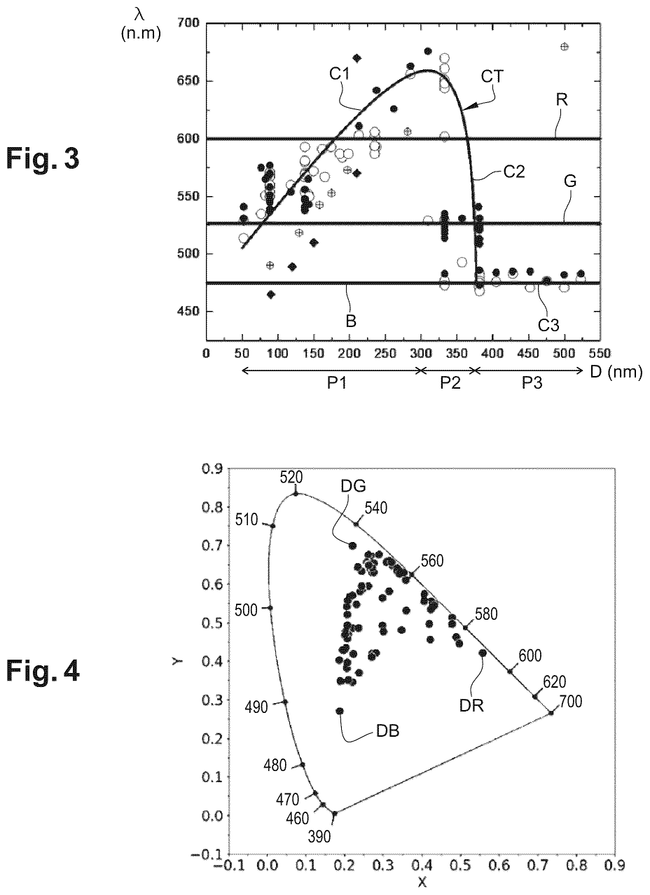

FIG. 3 gathers the results of these tests. The axis of ordinates shows the central wavelength λ, expressed in nanometers, of the radiation emitted by active regions 76, and the axis of abscissas shows the diameter D, expressed in nanometers, of wires 20. The results of a first series of tests are shown in FIG. 3 by white circles and the results of a second series of tests are shown in FIG. 3 by black circles. Curve CT is the curve of variation of wavelength λ according to diameter D, obtained by a cubic spline regression from the values obtained at the first and second tests. Horizontal lines R, G, and B respectively correspond to colors red, green, and blue.

As a comparison, black diamonds show the results disclosed in Kishino et al.'s publication entitled “Monolithic integration of four-colour InGaN-based nanocolumn LEDs” (Elec Letters 28th May 2015 Vol 51 pages 852-854), and hexagons containing a cross show the results disclosed in Mi et al.'s publication entitled “Tunable, Full-Color Nanowire Light Emitting Diode Arrays Monolithically Integrated on Si and Sapphire” (Proc. of SPIE Vol. 9748+, 2016). The comparison results have been obtained with GaN wires and active regions with a single InGaN quantum well. Further, the wires and the active regions were formed by MBE for Mi et al. and Kishino et al.'s publications. For the comparison results, an increase in the wavelength of the emitted radiation with the wire diameter can be observed. It is known that the wavelength of the radiation emitted by the active region increases when the proportion of indium in the quantum well(s) increases. The comparison results thus imply for the proportion of indium in the single quantum well to increase when the wire diameter increases.

The forming of the wires by MOCVD has enabled to form wires of greater diameters than what is generally achieved by MBE, so that after the forming of the active regions by MBE, it has been unexpectedly observed that variation curve CT successively comprises a first rising portion C1, for which the wavelength of the emitted radiation increases with the diameter of the wire, a second falling portion C2, for which the wavelength of the emitted radiation decreases with the diameter of the wire, and a third substantially constant portion C3, for which the wavelength of the emitted radiation varies little with the wire diameter.

According to an embodiment, first rising portion C1 is obtained for a wire diameter varying in a first range P1 from approximately 50 nm to approximately 300 nm. The wavelength of the radiation emitted over the first rising portion increases from approximately 510 nm to approximately 675 nm. According to an embodiment, the second falling portion C2 is obtained for a wire diameter varying in a second range P2 from approximately 300 nm to approximately 375 nm. The wavelength of the radiation emitted over the second falling portion decreases from approximately 675 nm to approximately 475 nm. According to an embodiment, the third constant portion C3 is obtained for a wire diameter in a third range P3 from approximately 375 nm to approximately 550 nm. The wavelength of the radiation emitted over the third constant portion varies between approximately 460 nm and 490 nm. As shown in FIG. 3, a light-emitting diode emitting in blue may be formed with a diameter in third range P3 and light-emitting diodes emitting in green and in red may be formed with a diameter in first range P1. A light-emitting diode emitting in green may be formed with a diameter in second range P2. However, in practice, the variability of the wavelength obtained according to the diameter may be too high for an application at an industrial scale.

A display pixel has been formed by forming first light-emitting diodes with wires 20 of small diameter D1, second light-emitting diodes with wires 22 of intermediate diameter D2, and third light-emitting diodes with wires 24 of large diameter D3.

FIG. 4 shows an XY chromaticity diagram having the results of the first and second tests indicated thereon by black circles. By selecting, to form display sub-pixels, the light-emitting diodes for which the radiations correspond to circles DR, DG, and DB closest to the “apexes” of the chromaticity diagram, it is possible to display an image pixel, the color of which can be obtained by combination of the colors corresponding to circles DR, DG, and DB. For circle DR, the diameter was equal to approximately 200 nm-250 nm. For circle DG, the diameter was equal to approximately 100 nm-150 nm. For circle DB, the diameter was greater than or equal to approximately 370 nm. There appears that a large portion of the chromaticity diagram can be reached.

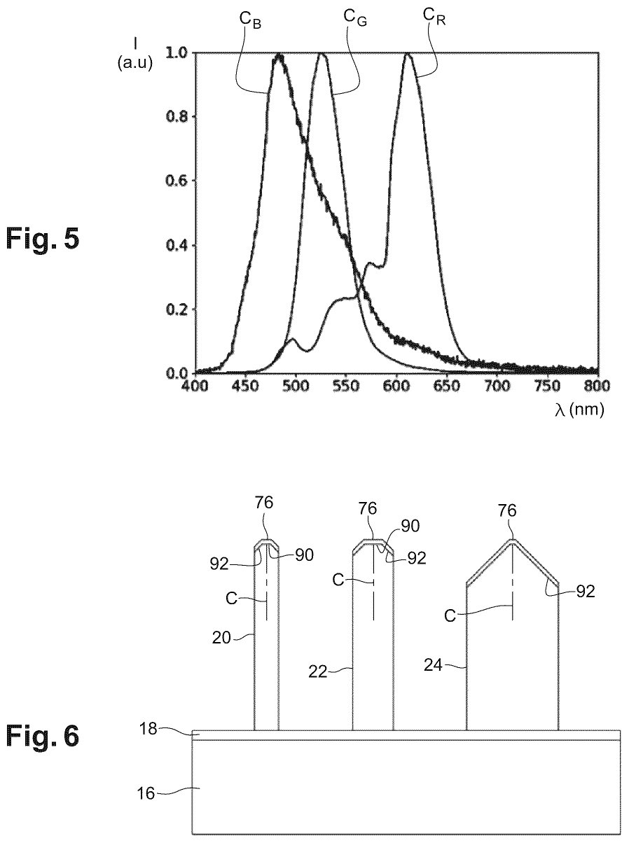

FIG. 5 shows curves C_{R}, C_{G}, and C_{B} of light intensity I, expressed in arbitrary units (a.u.), according to the wavelength λ, expressed in nanometers (nm), of the radiation respectively emitted by the light-emitting diodes corresponding to circles DR, DG, and DB in FIG. 4. As shown in this drawing, the spectrums of the radiations of these light-emitting diodes are relatively narrow.

FIG. 6 illustrates a possible explanation of the variation of the curve CT of FIG. 3. FIG. 6 very schematically shows three wires 20, 22, 24, without showing the associated active regions 76, semiconductor stacks 78 and conductive layers 42, 44, and 46. The upper portion of each wire 20, 22, 24 may comprise a c plane (surface 90 perpendicular to axis C) and/or semi-polar planes (surface 92 inclined with respect to axis C). Active region 76 is likely to cover a c plane and/or semi-polar planes. The optical properties of the portion of active region 76 covering a c plane are not the same as those of the portion of active region 76 covering semi-polar planes. In particular, the maximum rate of incorporation of the additional element into the portion of active area 76 covering a c plane is greater than the maximum rate of incorporation of the additional element into the portion of active area 76 covering semi-polar planes. An explanation of the variation of the curve CT of FIG. 3 would be the following: in the first range P1 of diameters, the contribution, in the general radiation emitted by active region 76, of the portion of active region 76 resting on a c plane is predominating over the contribution of the portion of active region 76 resting on semi-polar planes. Thereby, an increase in the wavelength of the general radiation with the wire diameter can be observed. In the second range P2 of diameters, the significances of the contribution in the general radiation of the portion of active region 76 resting on a c plane and of the contribution in the general radiation of the portion of active region 76 resting on semi-polar planes are inverted and, since the incorporation of indium into the portion of active region 76 resting on semi-polar planes is decreased, the central wavelength of the general radiation drops. In the third range P3 of diameters, the contribution of the portion of active region 76 resting on semi-polar planes in the general radiation emitted by active region 76 is predominating over the contribution of the portion of active region 76 resting on a c plane, which results in a stagnation of the central wavelength of the emitted radiation.

Considering FIG. 1 again, according to an embodiment, each display pixel of optoelectronic device 10 comprises at least three types of light-emitting diodes. According to an embodiment, the light-emitting diodes of the first type, for example comprising wires 20 and heads 26, are adapted to emitting a first radiation at a first central wavelength. The light-emitting diodes of the second type, for example comprising wires 22 and heads 28, are adapted to emitting a second radiation at a second central wavelength. The light-emitting diodes of the third type, for example comprising wires 24 and heads 30, are adapted to emitting a third radiation at a third central wavelength. The first, second, and third central wavelengths are different.

According to an embodiment, the first wavelength corresponds to green light and is in the range from 510 nm to 550 nm. According to an embodiment, the first diameter D1 varies from 80 nm to 150 nm. According to an embodiment, the second wavelength corresponds to red light and is in the range from 600 nm to 720 nm. According to an embodiment, the second diameter D2 varies from 200 nm to 350 nm. According to an embodiment, the third wavelength corresponds to blue light and is within the range from 430 nm to 490 nm. According to an embodiment, the third diameter D3 varies from 370 nm to 500 nm. Advantageously, as appears from FIG. 3, beyond a diameter equal to approximately 400 nm, the wavelength of the radiation emitted by active region 76 is little sensitive to the wire diameter.

According to an embodiment, each display pixel Pix comprises light-emitting diodes of a fourth type, the light-emitting diodes of the fourth type being adapted to emitting a fourth radiation at a fourth wavelength. The first, second, third, and fourth wavelengths may be different. According to an embodiment, the fourth wavelength corresponds to yellow light and is in the range from 570 nm to 600 nm, or to cyan and is in the range from 490 nm to 510 nm, or generally to any other color than the first, second, and third radiations.

According to an embodiment, for each display pixel, the elementary light-emitting diodes having wires of same diameter have a common electrode and, when a voltage is applied between conductive layer 18 and conductive layer 42, 44, or 46, a light radiation is emitted by the active areas of these elementary light-emitting diodes.

In the present embodiment, the electromagnetic radiation emitted by each light-emitting diode escapes from optoelectronic device 12 through surface 17. Preferably, each conductive layer 42, 44, 46 is reflective and advantageously enables to increase the proportion of the radiation emitted by the light-emitting diodes which escapes from optoelectronic device 10 through surface 17.

Optoelectronic chip 12 and control chip 14 being stacked, the lateral bulk of optoelectronic device 10 is decreased. According to an embodiment, the lateral dimension of a display pixel, measured perpendicularly to the wire axes, is smaller than 5 μm, preferably smaller than 4 μm, for example, equal to approximately 3 μm. Further, optoelectronic chip 12 may have the same dimensions as control chip 14. Thereby, the compactness of optoelectronic device 10 may advantageously be increased.

Conductive layer 18 is capable of biasing the active areas of heads 26, 28, 30 and of giving way to the electromagnetic radiation emitted by the light-emitting diodes. The material forming conductive layer 18 may be a transparent conductive material such as graphene or a transparent conductive oxide (TCO), particularly indium tin oxide (ITO), zinc oxide, doped or not with aluminum, or with gallium, or with boron, or silver nanowires. As an example, conductive layer 18 has a thickness in the range from 20 nm to 500 nm, preferably from 20 nm to 100 nm.

Conductive layer 38, conductive layers 42, 44, 46, 48, and conductive pads 52, 54, 56, 58 may be made of metal, for example, of aluminum, silver, platinum, nickel, copper, gold, or ruthenium, or of an alloy comprising at least two of these compounds, particularly the PdAgNiAu alloy or the PtAgNiAu alloy. Conductive layer 38 may have a thickness in the range from 100 nm to 3 μm. Conductive portions 42, 44, 46, 48 may have a thickness in the range from 100 nm to 2 μm. The minimum lateral dimension, in a plane perpendicular to surface 17, is in the range from 150 nm to 1 μm, for example, approximately 0.25 μm. Conductive pads 52, 54, 56, 58 may have a thickness in the range from 0.5 μm to 2 μm.

Each of insulating layers 16, 32, 34, and 50 is made of a material selected from the group comprising silicon oxide (SiO₂), silicon nitride (SiₓN_{y}, where x is approximately equal to 3 and y is approximately equal to 4, for example, Si₃N₄), silicon oxynitride (particularly of general formula SiOₓN_{y}, for example, Si₂ON₂), hafnium oxide (HfO₂), titanium oxide (TiO₂), or aluminum oxide (Al₂O₃). Layer 34 and/or layer 32 may further be made of an organic insulating material, for example, made of parylene or of benzocyclobutene (BCB). Insulating layer 16 may have a maximum thickness in the range from 100 nm to 5 μm. Insulating layers 32 and 34 may have a maximum thickness in the range from 0.5 μm to 2 μm. Insulating layer 50 may have a maximum thickness in the range from 0.5 μm to 2 μm.

Each wire 20, 22, 24 may have a semiconductor structure elongated along an axis substantially perpendicular to surface 17. Each wire 20, 22, 24 may have a generally cylindrical shape with a cross-section that may have different shapes, such as, for example, an oval, circular, or polygonal shape, particularly triangular, rectangular, square, or hexagonal. The axes of two adjacent wires 20, 22, 24 may be distant by from 100 nm to 3 μm and preferably from 200 nm to 1.5 μm. The height of each wire 20, 22, 24 may be in the range from 150 nm to 10 μm, preferably from 200 nm to 1 μm, more preferably from 250 nm to 750 nm. The mean diameter of each wire 20, 22, 24 may be in the range from 50 nm to 10 μm, preferably from 100 nm to 2 μm, more preferably from 120 nm to 1 μm.

According to an embodiment, wires 20, 22, 24 are simultaneously formed by MOCVD from a seed layer. The growth conditions in the reactor are adapted to favor the preferential growth of each wire 20, 22, 24 along its axis C. This means that the growth speed of a wire along axis C is much greater, preferably by at least one order of magnitude, than the growth speed of the wire along a direction perpendicular to axis C. In an example, the method may comprise the injection into a reactor of a precursor of a group-III element and of a precursor of a group-V element. Examples of precursors of group-III elements are trimethylgallium (TMGa), triethylgallium (TEGa), trimethylindium (TMIn), or trimethylaluminum (TMAl). Examples of precursors of group-V elements are ammonia (NH₃), tributylphosphate (TBP), arsine (AsH₃), or dimethylhydrazine (UDMH). Some of the precursor gases may be generated by using a water mixer and a carrier gas.

According to an embodiment, the temperature in the reactor is in the range from 900° C. to 1,065° C., preferably in the range from 1,000° C. to 1,065° C., in particular 1,050° C. According to an embodiment, the pressure in the reactor is in the range from 50 Torr (approximately 6.7 kPa) to 200 Torr (approximately 26.7 kPa), in particular 100 Torr (approximately 13.3 kPa). According to an embodiment, the flow rate of the precursor of the group-III element, for example, TEGa, is in the range from 500 sccm to 2,500 sccm, in particular, 1,155 sccm. According to an embodiment, the flow rate of the precursor of the group-V element, for example NH₃, is in the range from 65 sccm to 260 sccm, in particular 130 sccm. According to an embodiment, the ratio of the flow rate of the precursor gas of the group-V element injected into the reactor to the flow rate of the precursor gas of the group-III element injected into the reactor, called V/III ratio, is in the range from 5 to 15. The carrier gases may include N₂ and H₂. According to an embodiment, the percentage of hydrogen injected into the reactor is in the range from 3% to 15% by weight, in particular 5% by weight, with respect to the total mass of the carrier gases. The obtained growth speed of wire 34 may be in the range from 1 μm/h to 15 μm/h, in particular 5 μm/h.

A precursor for the dopant may be injected into the reactor. For example, when the dopant is Si, the precursor may be silane (SiH₄). The flow rate of the precursor may be selected to target an average dopant concentration in the range from 5*10¹⁸ to 5*10¹⁹ atoms/cm³, in particular 10¹⁹ atoms/cm³.

In another embodiment, semiconductor layer 70, when present, is grown on each wire by MBE. According to an embodiment, for the MBE growth of semiconductor layer 70, the temperature in the reactor is in the range from 800° C. to 900° C. According to an embodiment, the pressure in the reactor is in the range from 3*10⁻⁸ Torr (approximately 4*10⁻³ mPa) to 5*10⁻⁵ Torr (approximately 6.7 mPa). According to an embodiment, a plasma is created with an RF power between 300 W and 600 W, for example, 360 W. According to an embodiment, the temperature of the solid source of the group-III element, for example, Ga, is in the range from 800° C. to 1,000° C., particularly 850° C. According to an embodiment, the flow rate of the precursor gas of the group-V element, for example, N₂, is in the range from 0.5 sccm to 5 sccm, in particular 1.5 sccm.

A precursor for the dopant may be injected into the reactor. For example, when the dopant is Si, the precursor may be silane (SiH₄). The flow rate of the precursor may be selected to target an average dopant concentration in the range from 5*10¹⁸ to 2*10¹⁹ atoms/cm³, in particular 10¹⁹ atoms/cm³.

According to an embodiment, each layer of active region 76 is grown by MBE. In an embodiment, the MOCVD and MBE steps are carried out in different reactors. In an embodiment, the method may use for the MBE a solid/gaseous source precursor for the group-III element and for the group-V element. According to an embodiment, a solid source may be used when the group-III element is Ga and a gaseous or plasma precursor may be used when the group-V element is N. According to an embodiment, a beam of active nitrogen is supplied by a DC plasma source. In this source, excited neutral nitrogen molecules are formed in a region devoid of electric field and are accelerated towards the substrate by the pressure gradient with the vacuum chamber.

The forming of certain layers of active region 76, in particular quantum wells 86, may comprise injecting into the reactor a solid/gaseous precursor of an additional element. According to an embodiment, a solid source may be used when the additional group-III element is In, Ga, or Al. The speed of incorporation of the additional element into the active region 76 particularly depends on the lateral dimensions of active regions 76, on the distance between wires 20, 22, 24, and on the height of active regions 76 with respect to the support having wires 20, 22, 24 extending therefrom.

A dopant may be injected into the reactor. For example, when the dopant is made of Si, a solid source may be used. According to an embodiment, the temperature of the solid source of the dopant element is in the range from 1,000° C. to 1,200° C.

According to an embodiment, for the MBE growth of each barrier layer 88, the temperature in the reactor is in the range from 570° C. to 640° C., in particular 620° C. According to an embodiment, the pressure in the reactor is in the range from 3*10⁻⁸ Torr (approximately 4*10⁻³ mPa) to 5*10⁻⁵ Torr (approximately 6.7 mPa). According to an embodiment, a plasma is created with an RF power between 300 W and 600 W, for example, 360 W. According to an embodiment, the temperature of the solid source of the group-III element, for example, Ga, is in the range from 850° C. to 950° C., particularly 895° C. According to an embodiment, the flow rate of the precursor gas of the group-V element, for example, N₂, is in the range from 0.5 sccm to 5 sccm, in particular 1.5 sccm.

According to an embodiment, for the MBE growth of each quantum well 86, the temperature in the reactor is in the range from 570° C. to 640° C., in particular 620° C. According to an embodiment, the pressure in the reactor is in the range from 3*10⁻⁸ Torr (approximately 4*10⁻³ mPa) to 5*10⁻⁵ Torr (approximately 6.7 mPa). According to an embodiment, a plasma is created with an RF power between 300 W and 600 W, for example, 360 W. According to an embodiment, the temperature of the solid source of the group-III element, for example, Ga, is in the range from 850° C. to 950° C., particularly 895° C. According to an embodiment, the temperature of the solid source of the additional element, for example, In, is in the range from 750° C. to 900° C., particularly 790° C. According to an embodiment, the flow rate of the precursor gas of the group-V element, for example, N₂, is in the range from 0.5 sccm to 5 sccm, in particular 1.5 sccm.

According to an embodiment, each layer of semiconductor stack 78 is grown by MBE. According to an embodiment, semiconductor layer 80 is grown with substantially a c-plane orientation. According to an embodiment, for the MBE growth of electron-blocking layer 82, the temperature in the reactor is in the range from 700° C. to 900° C., in particular 800° C. According to an embodiment, the pressure in the reactor is in the range from 3*10⁻⁸ Torr (approximately 4*10⁻³ mPa) to 5*10⁻⁵ Torr (approximately 6.7 mPa). According to an embodiment, a plasma is created with an RF power between 300 W and 600 W, for example, 360 W. According to an embodiment, the temperature of the solid source of the group-III element, for example, Ga, is in the range from 850° C. to 950° C., particularly 905° C. According to an embodiment, the temperature of the solid source of the additional element, for example, Al, is in the range from 1,000° C. to 1,100° C., particularly 1,010° C. According to an embodiment, the flow rate of the precursor gas of the group-V element, for example, N₂, is in the range from 0.5 sccm to 5 sccm, in particular 1.5 sccm. A dopant may be injected into the reactor. For example, when the dopant is Mg, a solid source may be used. According to an embodiment, the temperature of the solid source of the dopant element is in the range from 150° C. to 350° C., in particular 190° C.

FIGS. 7A to 7N are partial simplified cross-section views of the structures obtained at successive steps of another embodiment of a method of manufacturing the optoelectronic device 10 shown in FIG. 1.

FIG. 7A shows the structure obtained after the steps of:

forming a support 100 corresponding to the stacking, from bottom to top in FIG. 7A, of a substrate 101, of at least one nucleation layer, also called seed layer, two nucleation layers 102 and 103 being shown as an example in FIG. 7A, of an electrically-insulating layer 104, and of an electrically-insulating layer 106 on insulating layer 104, insulating layers 104, 106 being made of different materials;

forming first openings 108 in insulating layers 104 and 106 to expose portions of nucleation layer 103 at the desired locations of first wires 20, the diameter of the first openings 108 substantially corresponding to the diameter of first wires 20, second openings 110 in insulating layers 104 and 106 to expose portions of nucleation layer 103 at the desired locations of second wires 22, the diameter of second openings 110 substantially corresponding to the diameter of the second wires 22, and third openings 112 in insulating layers 104 and 106 to expose portions of nucleation layers 103 at the desired locations of third wires 24, the diameter of third openings 112 substantially corresponding to the diameter of third wires 24;
simultaneously growing wires 20, 22, 24 by MOCVD from nucleation layer 103 in openings 108, 110, 112;
simultaneously growing heads 26, 28, 30 by MBE on wires 20, 22, 24, each head 26, 28, 30 comprising active region 76 and semiconductor stack 78.

As a variation, insulating layers 104, 106 may be replaced with a single insulating layer.

Substrate 101 may correspond to a monoblock structure or may correspond to a layer covering a support made of another material. Substrate 101 is preferably a semiconductor substrate, for example, a substrate made of silicon, of germanium, of silicon carbide, of a III-V compound, such as GaN or GaAs, or a ZnO substrate, or a conductive substrate, for example, a substrate made of a metal or a metal alloy, particularly copper, titanium, molybdenum, a nickel-based alloy, and steel. Preferably, substrate 101 is a single-crystal silicon substrate. Preferably, it is a semiconductor substrate compatible with manufacturing methods implemented in microelectronics. Substrate 101 may correspond to a multilayer structure of silicon-on-insulator type, also called SOI. Substrate 101 may be heavily doped, lightly-doped, or non-doped.

Nucleation layers 102, 103 are made of a material which favors the growth of wires 20, 22, 24. The material forming each nucleation layer 102, 103 may be a metal, a metal oxide, a nitride, a carbide, or a boride of a transition metal of column IV, V, or VI of the periodic table of elements or a combination of these compounds and preferably a nitride of a transition metal of column IV, V, or VI of the periodic table of elements, or a combination of these compounds. As an example, each seed layer 102, 103 may be made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbide nitride (TaCN), of magnesium nitride in MgₓN_{y} form, where x is approximately equal to 3 and y is approximately equal to 2, for example, magnesium nitride in Mg₃N₂ form. Each nucleation layer 102, 103 has, for example, a thickness in the range from 1 nm to 100 nm, preferably in the range from 10 nm to 30 nm.

Each of insulating layers 104 and 106 is made of a material selected from the group comprising silicon oxide (SiO₂), silicon nitride (SiₓN_{y}, where x is approximately equal to 3 and y is approximately equal to 4, for example, Si₃N₄), silicon oxynitride (particularly of general formula SiOₓN_{y}, for example, Si₂ON₂), hafnium oxide (HfO₂), or aluminum oxide (Al₂O₃). According to an embodiment, insulating layer 104 is made of silicon oxide and insulating layer 106 is made of silicon nitride. The thickness of each insulating layer 104, 106 is in the range from 10 nm to 100 nm, preferably from 20 nm to 60 nm, particularly equal to approximately 40 nm.

The growth method of wires 20, 22, 24 is the MOCVD method such as previously described. The height of each wire 20, 22, 24 at the end of the growth step may be in the range from 250 nm to 15 μm, preferably from 500 nm to 5 μm, more preferably from 1 μm to 3 μm. The height of the first wires 20 is different from the height of the second wires 22 and from the height of the third wires 24. The height of wires 20, 22, 24 particularly depends on the wire diameter and on the distance between wires. According to an embodiment, the height of the first wires 20 is greater than the height of the second wires 22 and the height of the second wires 22 is greater than the height of the third wires 24.

Each seed layer 102, 103 and each insulating layer 104, 106 may be deposited as an example by plasma-enhanced chemical vapor deposition (PECVD), low-pressure chemical vapor deposition (LPCVD), sub-atmospheric chemical vapor deposition (SACVD), CVD, physical vapor deposition (PVD), or atomic layer deposition (ALD).

FIG. 7B shows the structure obtained after having deposited a dielectric layer 113 over all the wires 20, 22, 24 and over insulating layer 106 between wires 20, 22, 24.

Dielectric layer 113 may be made of the same material as insulating layer 106. According to an embodiment, the minimum thickness of layer 113 is greater than the sum of the height of the smallest wires 20, 22, 24 and of the height of the associated head 26, 28, 30. Preferably, the minimum thickness of layer 113 is greater than the sum of the height of the largest wires 20, 22, 24 and of the height of the associated head 26, 28, 30.

As an example, the thickness of dielectric layer 113 is in the range from 250 nm to 15 μm, preferably from 300 nm to 5 μm, for example, equal to approximately 2 μm. Insulating layer 113 may be formed by the same methods as those used to form insulating layers 104, 106.

FIG. 7C shows the structure obtained after having thinned and planarized insulating layer 113 and a portion of heads 26, 28, 30 to delimit a planar surface 114 at a height of insulating layer 106 for example in the range from 150 nm to 10 μm. The etching is for example a CMP (Chemical-Mechanical Planarization). The presence of insulating layer 113 between wires 20, 22, 24 enables to implement a CMP-type etch method, which would be difficult or even impossible if only the wires were present. After this step, all wire-head assemblies 20-26, 22-28, 24-30 have the same height. The etching of insulating layer 113 and of a portion of wires 20, 22, 24 may be carried out in a plurality of steps. As a variant, the step of thinning and of planarization of insulating layer 83 and of a portion of heads 26, 28, 30 may not be present when the wire-head assemblies 20-26, 22-28, 24-30 have substantially the same height.

FIG. 7D shows the structure obtained after having fully removed dielectric layer 113 to expose insulating layer 106 and wire-head assemblies 20-26, 22-28, 24-30. Insulating layer 106 may then play the role of an etch stop layer during the etching of dielectric layer 113. The removal of dielectric layer 113 may be performed by a wet etching. As a variation, the etching of dielectric layer 113 may be only partial, a residual layer being kept on insulating layer 106.

FIG. 7E shows the structure obtained after the steps of:
forming of insulating layer 32;
forming of insulating layer 34; and
etching or thinning insulating layer 34 across part of its thickness to delimit a substantially planar surface 116.

Insulating layer 32 may be formed by conformal deposition, for example, by LPCVD. The method of forming insulating layer 32 is preferably carried out at a temperature lower than 700° C. to avoid damaging the active regions of the light-emitting diodes. Further, an LPCVD-type method enables to obtain a good filling between wires 20, 22, 24. The deposited thickness of insulating layer 32 may be in the range from 100 nm to 1 μm, for example, approximately 500 nm. Insulating layer 34 may for example be formed by conformal deposition, for example, by PECVD. The deposited thickness of insulating layer 34 may be greater than or equal to 2 μm. The partial etching of insulating layer 34 may be performed by CMP. The stopping of the etching may be performed in insulating layer 34, as shown in FIG. 7E, or insulating layer 32, but in any case before exposing heads 26, 28, 30.

FIG. 7F shows the structure obtained after having etched insulating layers 32, 34, to expose the upper surfaces of heads 26, 28, 30. The etching is for example an etching of reactive ion etching type (RIE) or an inductively coupled plasma etching (ICP). Since heads 26, 28, 30 may have different dimensions, some heads 26, 28, 30 may be more exposed than others. Heads 26, 28, 30 are not etched at this step. The etching is preferably an anisotropic etching. Portions, not shown, of layer 32 may be kept on the lateral walls of heads 26, 28, 30. The layer located at the top of heads 26, 28, 30 plays the role of an etch stop layer. According to an embodiment, on forming of heads 26, 28, 30, an additional layer is added at the top of heads 26, 28, 30 to play the role of an etch stop layer. It may be an AlN layer.

FIG. 7G shows the structure obtained after the following steps:
when etch stop layers are present on heads 26, 28, 30, removal of the etch stop layers;
deposition of a metal layer on the structure shown in FIG. 7E, for example, by cathode sputtering, for example having a 0.5-μm thickness;
etching of the metal layer to delimit conductive layers 42, 44, 46, 48.

When the etch stop layers on heads 26, 28, 30 are made of AN, they may be removed by an etching of tetramethylammonium hydroxide type (TMAH). Before the forming of conductive layers 42, 44, 46, 48, separate metal portions may be formed over the entire structure. This may be performed by the deposition of a metal layer having a 1-nm thickness, for example, nickel or platinum, and a thermal anneal step, for example, at a 550° C. temperature, which results in the forming of the separate portions.

FIG. 7H shows the structure obtained after the steps of:
depositing insulating layer 50 on the structure shown in FIG. 7G; and
forming conductive pads 52, 54, 56, 58, for example, made of copper.

FIG. 7I shows the structure obtained after having bonded control chip 14 to optoelectronic chip 12. The bonding of control chip 14 to optoelectronic chip 12 may be performed by using inserts such as connection microballs, not shown. As a variation, the bonding of control chip 14 to the optoelectronic chip may be performed by direct bonding, without using inserts. The direction bonding may comprise a direct metal-to-metal bonding of metal areas, particularly the conductive pads 62, of control chip 14, and of metal areas, particularly the conductive pads 52, 54, 56, 58, of optoelectronic chip 12, and a dielectric-to-dielectric bonding of dielectric areas, particularly the insulating layer 50 of control chip 14, and of dielectric areas, particularly the insulating layer 50, of optoelectronic chip 12. The bonding of control chip 14 to optoelectronic chip 12 may be performed by a thermocompression method where optoelectronic chip 12 is pressed against control chip 14 with the application of a pressure and of a heating.

FIG. 7J shows the structure obtained after the steps of:
removal of substrate 101;
removal of seed layers 102, 103;
removal of insulating layers 104 and 106;
partial etching of insulating layer 32, of insulating layer 34, and of wires 20, 22, 24 to delimit a substantially planar surface 118.

The removal of substrate 101 may be performed by grinding and/or wet etching. The removal of seed layers 102, 103, of insulating layer 32, of insulating layer 34, and of wires 20, 22, 24 may be performed by wet etching, dry etching, or by CMP. Insulating layer 104 or 106 may play the role of an etch stop layer during the etching of seed layer 103.

FIG. 7K shows the structure obtained after having formed conductive layer 18 on surface 118, for example, by depositing a TCO layer over the entire surface 118, for example having a 50-nm thickness, and by etching this layer by photolithography techniques to only keep TCO layer 18.

FIG. 7L shows the structure obtained after having etched opening 36 in insulating layer 34 across the entire thickness of insulating layer 34 to expose conductive layer 48. This may be carried out by photolithography techniques.

FIG. 7M shows the structure obtained after having formed conductive layer 38 in opening 36 and on surface 118 in contact with conductive layer 18. This may be performed by depositing a stack of conductive layers, for example, of type Ti/TiN/AlCu, over the entire structure on the side of surface 118, and by etching this stack by photolithography techniques to only keep conductive layer 38.

FIG. 7N shows the structure obtained after having formed, on conductive layer 18, the insulating layer 16 delimiting surface 17. It for example is a SiON layer deposited by PECVD with a 1-μm thickness.

An additional step of forming raised areas on surface 17, also called texturing step, may be provided to increase the extraction of light.

The decrease in the wire height from the back side may be carried out by a CMP-type method, as previously described, or by any other dry etching or wet etching method. The obtained height of the wires, particularly made of GaN, may be selected to increase the extraction of light from the foot of the wire by optical interactions within the wire itself. Further, this height may be selected to favor the optical coupling between the different wires and thus to increase the collective emission of an assembly of wires.

Various embodiments and variants have been described. Those skilled in the art will understand that certain features of these various embodiments and variants may be combined, and other variants will occur to those skilled in the art. In particular, although, in the previously-described embodiments, the optoelectronic device comprises two chips bonded to each other, it is clear that the optoelectronic device may comprise a single chip, the electronic light-emitting diode control circuit being formed in integrated fashion with the light-emitting diodes. Finally, the practical implementation of the described embodiments and variations is within the abilities of those skilled in the art based on the functional indications given hereabove.

1. Optoelectronic device comprising first, second, and third three-dimensional light-emitting diodes with an axial configuration, each light-emitting diode comprising a semiconductor element and an active region resting on the semiconductor element, each semiconductor element corresponding to a microwire, a nanowire, a nanometer- or micrometer-range conical element, or a nanometer- or micrometer-range frustoconical element, the first light-emitting diodes being configured to emit a first radiation at a first wavelength, the semiconductor elements of the first light-emitting diodes having a first diameter, the second light-emitting diodes being configured to emit a second radiation at a second wavelength, the semiconductor elements of the second light-emitting diodes having a second diameter, and the third light-emitting diodes being configured to emit a third radiation at a third wavelength, the semiconductor elements of the third light-emitting diodes having a third diameter, the first diameter being smaller than the second diameter and the second diameter being smaller than the third diameter, the first wavelength being greater than the third wavelength and the second wavelength being greater than the first wavelength.

2. Optoelectronic device according to claim 1, wherein the first diameter varies from 80 nm to 150 nm.

3. Optoelectronic device according to claim 1, wherein the second diameter varies from 200 nm to 350 nm.

4. Optoelectronic device according to claim 1, wherein the third diameter varies from 370 nm to 500 nm.

5. Optoelectronic device according to claim 1, wherein the first wavelength is in the range from 510 nm to 570 nm.

6. Optoelectronic device according to claim 1, wherein the second wavelength is in the range from 600 nm to 720 nm.

7. Optoelectronic device according to claim 1, wherein the third wavelength is in the range from 430 nm to 490 nm.

8. Optoelectronic device according to any of claim 1, comprising a first optoelectronic circuit bonded to a second electronic circuit, the second electronic circuit comprising electrically-conductive pads, the first optoelectronic circuit comprising pixels and comprising, for each pixel:
a first electrically-conductive layer;
for each of the first, second, and third light-emitting diodes, said semiconductor element extending perpendicularly to the first electrically-conductive layer and in contact with the first electrically-conductive layer and the active region resting on the end of the semiconductor element opposite to the first electrically-conductive layer; and
second, third, fourth, and fifth electrically-conductive layers electrically coupled to the electrically-conductive pads, the second electrically-conductive layer being coupled to the active regions of the first light-emitting diodes, the third electrically-conductive layer being coupled to the active regions of the second light-emitting diodes, the fourth electrically-conductive layer being coupled to the active regions of the third light-emitting diodes, and the fifth electrically-conductive layer being coupled to the first electrically-conductive layer.

9. Optoelectronic device according to claim 1, wherein each active region comprises a single quantum well or multiple quantum wells.

10. Optoelectronic device according to claim 1, wherein the semiconductor elements and the active regions are made of III-V compounds.

11. Optoelectronic device according to claim 1, wherein the semiconductor elements of the first, second, and third light-emitting diodes are formed by MOCVD.

12. Optoelectronic device according to claim 1, wherein the active regions of the first, second, and third light-emitting diodes are formed by MBE.

13. Optoelectronic device according to claim 1, wherein the semiconductor elements of the first, second, and third light-emitting diodes rest on a substrate and are in contact with a material adapted to the epitaxial growth of the semiconductor elements the first, second, and third light-emitting diodes.

14. Optoelectronic device according to claim 1, wherein the first, second, and third light-emitting diodes form a monolithic structure.

15. Method of manufacturing the optoelectronic device according to claim 1, comprising the successive steps of:
simultaneously forming the semiconductor elements of the first, second, and third light-emitting diodes; and
simultaneously forming the active regions of the first, second, and third light-emitting diodes on the semiconductor elements of the first, second, and third light-emitting diodes.

16. Method according to claim 15, wherein the semiconductor elements of the first, second, and third light-emitting diodes are formed by MOCVD.

17. Method according to claim 15, wherein the active regions of the first, second, and third light-emitting diodes are formed by MBE.

18. Method according to claim 15, comprising the successive steps of:
simultaneously forming on a support the semiconductor elements of the first, second, and third light-emitting diodes and forming the active regions of the first, second, and third light-emitting diodes on the semiconductor elements of the first, second, and third light-emitting diodes;
forming an electrically-insulating layer between the three-dimensional semiconductor elements of the first, second, and third light-emitting diodes; and
removing the support.
